(19) United States
(12) Patent Application Publication
(10) Pub. No.: US 2011/0207302 A1
(43) Pub. Date: Aug. 25, 2011

(54) SEMICONDUCTOR DEVICE MANUFACTURING METHOD, AND SUBSTRATE PROCESSING METHOD AND APPARATUS

(75) Inventors: Jie WANG, Toyama-shi (JP); Osamu KASAHARA, Toyama-shi (JP); Kazuhiro YUASA, Toyama-shi (JP); Keigo NISHIDA, Toyama-shi (JP)

(73) Assignee: HITACHI KOKUSAI ELECTRIC INC., Tokyo (JP)

(21) Appl. No.: 13/033,095

(22) Filed: Feb. 23, 2011

(30) Foreign Application Priority Data
Feb. 24, 2010 (JP) 2010-038599

(51) Int. Cl. H01L 21/20; H01L 21/316; H01L 21/306

(52) U.S. Cl. 438/486; 438/770; 156/345.29; 257/E21.09; 257/E21.282

(57) ABSTRACT

Embodiments described herein relate to improving the quality of a substrate and the performance of a semiconductor device, which is caused by contaminates or particles being engrained into a substrate with a silicon film formed thereon, and forming a silicon film with a small surface roughness. Provided is a semiconductor device manufacturing method that includes forming a silicon film on a substrate, supplying an oxidation seed onto the substrate, performing heat treatment on the silicon film, modifying the surface layer of the silicon film into an oxidized silicon film, and removing the oxidized silicon film.

### CROSS-REFERENCE TO RELATED APPLICATIONS

This application is based upon and claims the benefit of priority from Japanese Patent Application No. 2010-038599, filed on Feb. 24, 2010, the entire contents of which is incorporated herein by reference.

### TECHNICAL FIELD

The present disclosure relates to a semiconductor device manufacturing method including a substrate processing, and a substrate processing method and apparatus, and more particularly relates to forming a silicon (Si) film on a substrate.

### BACKGROUND

As one of processes for manufacturing a semiconductor device, a process has been introduced where an FG (floating gate) structure with a silicon film, or TCAT (Terabit Cell Array Transistor) and BICS (Bit-Cost Scalable) having a silicon film used as a longitudinal transistor channel is applied to avoid interference between adjacent cells and bit-cost reduction in a 2×nm-scale NAND flash memory or beyond.

Unfortunately, in applying a silicon film in the above structure, it is difficult to control the degree of surface roughness (in RMS) of the silicon film, which makes it difficult to maintain a high carrier mobility. In addition, if the above structure is employed as a part of the semiconductor device, full performance of the semiconductor device may not be realized, resulting in a decrease in throughput.

On the other hand, in Japanese Patent Application Laid-Open No. 1995-249600, after a silicon film is formed, the planarization of the silicon film is performed by polishing the surface thereof by means of an abrasive.

However, during the process of polishing the surface of the silicon film, contaminates or particles may be engrained with the substrate and silicon film formed thereon, leading to deterioration in the quality of the substrate or the performance of a semiconductor device including the substrate.

### SUMMARY

To address the above problems of the background, the present disclosure provides in some embodiments a semiconductor device manufacturing method, and a substrate treatment method and apparatus which improves the quality of the substrate and the performance of the semiconductor device.

According to one embodiment of the present disclosure, a semiconductor device manufacturing method includes: forming a silicon film on a substrate; supplying an oxidation seed onto the substrate; performing heat treatment on the silicon film; modifying the surface layer of the silicon film into an oxidized silicon film; and removing the oxidized silicon film.

According to another embodiment of the present disclosure, provided is a substrate treatment apparatus that includes: a process chamber where a substrate is processed; a silicon-containing gas supply system configured to supply at least a silicon-containing gas into the process chamber; an oxygen-containing gas supply system configured to supply at least an oxygen-containing gas into the process chamber; a halogen-containing gas supply system configured to supply at least a halogen-containing gas into the process chamber; and a controller configured to control the silicon-containing gas supply system to supply at least the silicon-containing gas into the process chamber to thereby form the silicon film on the substrate, control the oxygen-containing gas supply system to supply the oxygen-containing gas into the process chamber to perform heat treatment on the silicon film, and to modify the surface layer of the silicon film into an oxidized silicon film, and control the halogen-containing gas supply system to supply the halogen-containing gas into the process chamber to remove the oxidized silicon film.

According to another embodiment of the present disclosure, provided is a substrate processing method, comprising: forming a silicon film on a substrate; supplying an oxidation seed onto the substrate, performing heat treatment on the silicon film, and modifying the surface layer of the silicon film into an oxidized silicon film; and removing the oxidized silicon film.

### BRIEF DESCRIPTION OF THE DRAWINGS

FIG. 1 is a perspective view showing a configuration of a semiconductor manufacturing apparatus 10 according to a first embodiment of the present disclosure.

FIG. 2 is a schematic side-elevational view showing a process furnace 202 in the semiconductor manufacturing apparatus 10 and a configuration of controlling respective parts thereof according to the first embodiment of the present disclosure.

FIG. 3 is a schematic sectional view showing a state of a substrate formed at respective processes according to the first embodiment of the present disclosure.

FIG. 4 is a schematic sectional view showing a state of a substrate formed at respective processes in a sample formation method.

FIG. 5 shows the result of the comparison between a surface roughness of the film formed according to the first embodiment and that of a sample film.

FIG. 6 shows the relationship between film thickness values and in-surface uniformities measured at the respective film thickness values in an amorphous silicon film.

### DETAILED DESCRIPTION

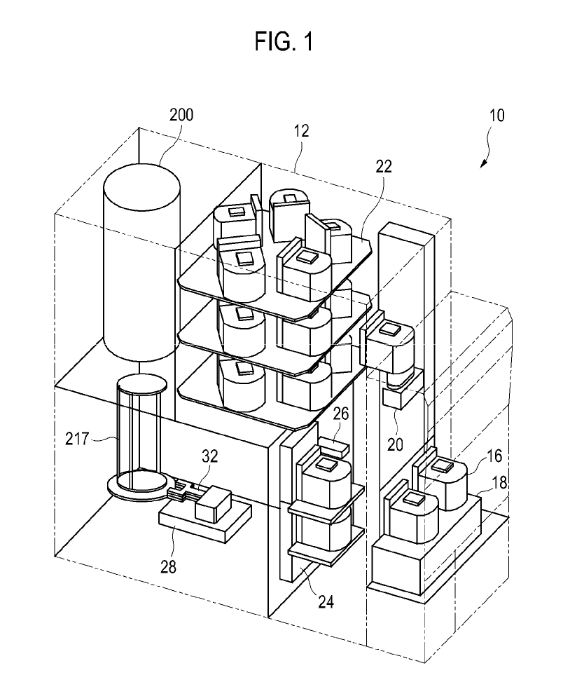

A first embodiment of the present disclosure will now be described with reference to the drawings. FIG. 1 is a perspective view showing a configuration of a semiconductor manufacturing apparatus 10 used as a substrate process apparatus according to a first illustrative embodiment of the present disclosure. The semiconductor manufacturing apparatus 10, which is a batch-type vertical thermal process apparatus, may include a housing 12 in which main parts of the apparatus are mounted. In the semiconductor manufacturing apparatus 10, a foup (substrate container; hereinafter referred to as pod) 16 is disposed which is used as a wafer carrier accommodating therein a wafer (used as substrate) 200 made of silicon (Si), silicon carbide (SiC) or the like. Disposed in the front side of the housing 12 is a pod stage 18 to which the pod 16 is carried. The pod 16 may accommodate, for example, 25 wafers 200 therein and is placed on the pod stage 18 with a cover of the pod 16 closed.

A pod carrier 20 is disposed in the front side inside the housing 12 at a position opposite the pod stage 18. A pod shelf 22, a pod opener 24 and a substrate number detecting part 26 are disposed in the vicinity of the pod carrier 20. The pod shelf 22 is disposed above the pod opener 24 and is configured to hold a plurality of the pods 16 loaded thereon. The substrate number detecting part 26 is disposed adjacent to the pod opener 24. The pod carrier 20 acts to carry the pod 16 between the pod stage 18, the pod shelf 22 and the pod opener 24. The pod opener 24 acts to open the cover of the pod 16, and the substrate number detecting part 26 acts to detect the number of the wafers 200 loaded in the pod 16 while its cover is open.

Disposed inside the housing 12 are a substrate transfer part 28 and a boat 217 that serves as a substrate support. The substrate transfer part 28 is equipped with an arm (tweezer) 32 and is rotatable and vertically movable by means of a drive mechanism (not shown). The arm 32 acts to pick up, for example, five wafers 200, and is operated to transfer the wafers 200 between the boat 217 and the pod 16 placed at the same position of the pod opener 24.

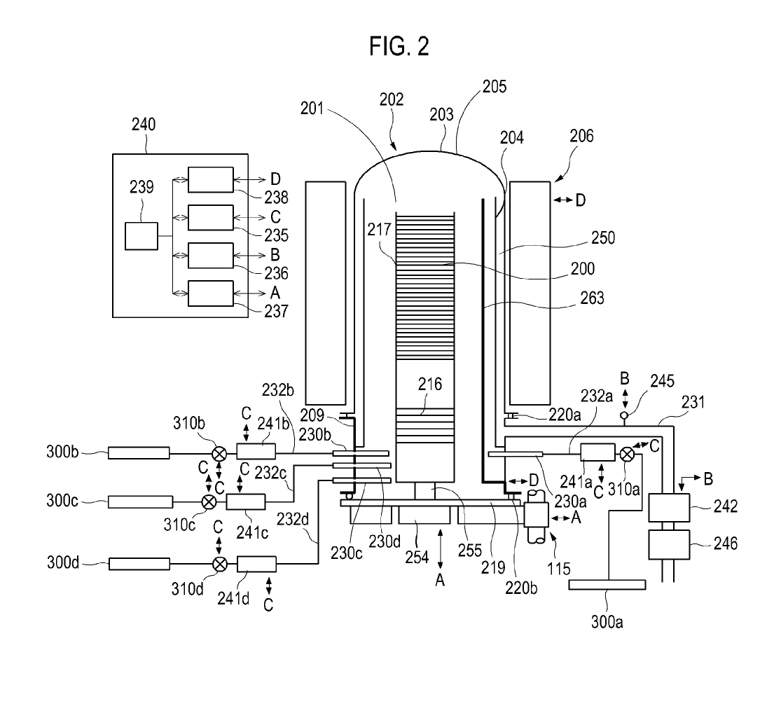

FIG. 2 is a schematic side-elevational view showing a configuration of a process furnace 202 in the substrate process apparatus used in an illustrative embodiment of the present disclosure.

As shown in FIG. 2, the process furnace 202 includes a heater 206 as a heating mechanism. The heater 206 is formed in, for example, a tubular shape and is vertically arranged by being supported by a heater base used as a holding plate (not shown).

Inside the heater 206, a process tube 203 that functions as a reaction tube is disposed concentrically with the heater 206. The process tube 203 may include an inner tube 204 as an inner reaction tube, and an outer tube 205 as an outer reaction tube which is mounted outside the inner tube 204. The inner tube 204 may be formed of a thermally-resistant material such as quartz (SiO₂), silicon carbide (SiC) or the like, and may be formed in a tubular shape that is opened at upper and lower ends. In a hollow portion of the tubular shaped inner tube 204, a process chamber 201 is formed, which is structured to accommodate wafers 200 (used as a substrate) at its level so that the wafers 200 are horizontally stacked by the boat 217 that will be described later. The outer tube 205 may be formed of a thermally-resistant material such as quartz (SiO₂), silicon carbide (SiC) or the like, and may be formed in a tubular shape that is closed at the upper end and open at the lower end. The internal diameter of the outer tube 205 is greater than the external diameter of the inner tube 204 while the outer tube 205 is formed concentrically with respect to the inner tube 204.

Beneath the outer tube 205, a manifold 209 is concentrically disposed with respect to the outer tube 205. The manifold 209 may be made of, for example, stainless steel or the like, and may be formed in a tubular shape that is open at upper and lower ends. The manifold 209 is engaged with the inner tube 204 and the outer tube 205 to support them. Further, an O-ring 220a as a seal member is disposed between the manifold 209 and the outer tube 205. The manifold 209 is supported by the heater base (not shown) so that the process tube 203 is vertically arranged. The process tube 203 and the manifold 209 constitute a reaction container.

Nozzles 230a, 230b, 230c and 230d are utilized as gas introducing parts and are connected to the manifold 209 so that they are in communication with the process chamber 201. Gas supply tubes 232a, 232b, 232c and 232d are connected to the nozzles 230a, 230b, 230c and 230d, respectively. A silicon-containing gas supply source 300a, a oxygen-containing gas supply source 300b, a halogen-containing gas supply source 300c and an inert gas supply source 300d are connected to the upstream side of the respective gas supply tubes 232a, 232b, 232c and 232d, which are located opposite the connection side and the respective nozzles 230a, 230b, 230c and 230d, via respective mass flow controllers (MFCs) 241a, 241b, 241c and 241d (which act as a gas flow rate controller) and respective valves 310a, 310b, 310c and 310d (which act as a switchgear). A gas flow rate control part 235 is electrically connected to the MFCs 241a, 241b, 241c and 241d (as depicted by C in FIG. 2), and is configured to control the flow rates of the gases being supplied, and to maintain desired values at desired times.

The nozzle 230a, which supplies for example, silane (SiH₄) gas as the silicon-containing gas, may be made of for example quartz, and is mounted to the manifold 209 to pass therethrough. At least one of the nozzles 230a may be mounted on the manifold 209, and is mounted beneath a position opposite the heater 206 and at a position opposite the manifold 209, thereby supplying the silicon-containing gas into the process chamber 201. The nozzle 230a is connected to the gas supply tube 232a. The gas supply tube 232a is connected to the silicon-containing gas supply source 300a which supplies the silicon-containing gas, for example, silane (SiH₄) gas, via the mass flow controller 241a which acts as a flow rate controller (a flow rate controlling means) and the valve 310a. This arrangement allows for the control over the conditions of the silicon-containing gas, for example, a supply flow rate, a concentration and a partial pressure of silane gas to be supplied into the process chamber 201. Mainly, the silicon-containing gas supply source 300a, the valve 310a, the mass flow controller 241a, the gas supply tube 232a and the nozzle 230a constitute a silicon-containing gas supply system as a gas supply system.

The nozzle 230b, which supplies for example, oxygen (O₂) gas as the oxygen-containing gas, may be made of for example quartz, and is mounted to the manifold 209 to pass therethrough. At least one of the nozzles 230b may be mounted on the manifold 209, and is mounted beneath a position opposite the heater 206 and at a position opposite the manifold 209, thereby supplying the oxygen-containing gas into the process chamber 201. The nozzle 230b is connected to the gas supply tube 232b. The gas supply tube 232b is connected to the oxygen-containing gas supply source 300b which supplies the oxygen-containing gas, for example, oxygen gas, via the mass flow controller 241b which acts as a flow rate controller (a flow rate controlling means) and the valve 310b. This arrangement allows for control over the conditions of the oxygen-containing gas, for example, a supply flow rate, a concentration and a partial pressure of oxygen gas to be supplied into the process chamber 201. Mainly, the oxygen-containing gas supply source 300b, the valve 310b, the mass flow controller 241b, the gas supply tube 232b and the nozzle 230b constitute an oxygen-containing gas supply system which acts as a gas supply system.

The nozzle 230c, which supplies for example, nitrogen trifluoride (NF₃) gas as the halogen-containing gas, may be made of for example quartz, and is mounted to the manifold 209 to pass therethrough. At least one of the nozzles 230c may be mounted on the manifold 209, and is mounted beneath a position opposite the heater 206 and at a position opposite the manifold 209, thereby supplying the halogen-containing gas into the process chamber 201. The nozzle 230c is connected to the gas supply tube 232c. The gas supply tube 232c is connected to the halogen-containing gas supply source 300c which supplies the halogen-containing gas, for example, nitrogen trifluoride (NF₃) gas, via the mass flow controller 241c which acts as a flow rate controller (a flow rate controlling means) and the valve 310c. This arrangement allows for control over the conditions of the halogen-containing gas, for example, a supply flow rate, a concentration and a partial pressure of nitrogen trifluoride gas to be supplied into the process chamber 201. Mainly, the halogen-containing gas supply source 300c, the valve 310c, the mass flow controller 241c, the gas supply tube 232c and the nozzle 230c constitute a halogen-containing gas supply system which acts as a gas supply system.

The nozzle 230d, which supplies for example, nitrogen (N₂) gas as the inert gas, may be made of for example quartz, and is mounted to the manifold 209 to pass therethrough. At least one of the nozzles 230d may be mounted on the manifold 209, and is mounted beneath a position opposite the heater 206 and at a position opposite the manifold 209, thereby supplying the inert gas into the process chamber 201. The nozzle 230d is connected to the gas supply tube 232d. The gas supply tube 232d is connected to the inert gas supply source 300d which supplies the inert gas, for example, nitrogen gas, via the mass flow controller 241d which acts as a flow rate controller (a flow rate controlling means) and the valve 310d. This arrangement allows for control over the conditions of the inert gas, for example, a supply flow rate, a concentration and a partial pressure to be supplied into the process chamber 201. Mainly, the inert gas supply source 300d, the valve 310d, the mass flow controller 241d, the gas supply tube 232d and the nozzle 230d constitute an inert gas supply system act as a gas supply system.

The gas flow rate control part 235 is electrically connected to the valves 310a, 310b, 310c and 310d and the mass flow controllers 241a, 241b, 241c and 241d (as indicated by C in FIG. 2) to control a desired gas supply amount, a gas supply start, a gas supply stop or the like at desired times.

Further, while in the embodiment explained above, the nozzles 230a, 230b, 230c and 230d are mounted at the position opposite the manifold 209, the present disclosure is not limited thereto. For example, in other embodiments, at least one of the nozzles 230a, 230b, 230c and 230d may be mounted at a position opposite the heater 206, thereby making it possible to supply the silicon-containing gas, the oxygen-containing gas, the halogen-containing gas or the inert gas in a wafer processing area. One or more nozzles formed in, for example, an L-shape, may be employed to extend a gas supply position to the wafer processing area so that the gas may be supplied from one or more positions to an area in the vicinity of the wafer. The nozzle(s) may be mounted at any one of the positions opposite the manifold 209 or the heater 206.

Further, while in the present embodiment the silane gas has been explained as one example of a silicon-containing gas, the present disclosure is not limited thereto. For example, in other embodiments, the silicon-containing gas may include a high-order silane gas such as disilane (Si₂H₆) gas, trisilane (Si₃H₈) gas or the like, dichlorosilane (SiH₂Cl₂) gas, trichlorosilane (SiHCl₃) gas, tetrachloro (SiCl₄) gas, or any combination thereof.

Further, while in the present embodiment, the oxygen (O₂) gas has been explained as one example of the oxygen-containing gas, the present disclosure is not limited thereto. For example, in other embodiments, the oxygen-containing gas may include ozone (O₃) gas or the like.

Further, while in the present embodiment, the nitrogen trifluoride (NF₃) gas has been explained as one example of the halogen-containing gas, the present disclosure is not limited thereto. For example, in other embodiments, the halogen-containing gas may include fluorine (F) or chlorine (Cl) such as chlorine trifluoride (ClF₃) gas, fluorine (F₂) gas or the like, or any combination thereof.

Further, while in the present embodiment, the nitrogen (N₂) gas has been explained as one example of the inert gas, the present disclosure is not limited thereto. For example, in other embodiments, the inert gas may include a rare gas such as helium (He) gas, neon (Ne) gas, argon (Ar) gas or the like, or a combination of the nitrogen gas and the rare gas.

An exhaust tube 231, which evacuates atmosphere inside the process chamber 201, is disposed on the manifold 209. The exhaust tube 231 is disposed at the lower end portion of a tubular space 250 that is formed by the gap between the inner tube 204 and the outer tube 205, so that this tube communicates with the tubular space 250. A vacuum exhaust equipment 246 such as a vacuum pump or the like is connected via a pressure sensor 245 (used as a pressure detector) and a pressure adjusting equipment 242 to the downstream side of the exhaust tube 231, which is opposite the side connected to the manifold 209. The vacuum exhaust equipment 246 is configured to create a vacuum in the process chamber 201 so that the pressure in the process chamber 201 is maintained at a desired pressure. A pressure control part 236 is electrically connected to the pressure adjusting equipment 242 and the pressure sensor 245 (as indicated by B in FIG. 2). The pressure control part 236 is configured to control the pressure adjusting equipment 242 at a desired time to adjust the pressure in the process chamber 201 to be maintained at a desired pressure, based on pressure information detected by the pressure sensor 245.

A sealing cap 219 is disposed beneath the manifold 209 to be used as a furnace opening cover that creates an air-tight seal in the lower opening of the manifold 209. The sealing cap 219 abuts on the lower end of the manifold 209 at its top face in the vertical direction. The sealing cap 219 may be made of a metallic material such as stainless or the like, and may be disc-shaped. An O-ring 220b used as a sealing member is disposed on the upper surface of the sealing cap 219, abutting on the lower end of the manifold 209 at its top face. A rotating mechanism 254 that rotates the boat 217 is mounted on one side of the sealing cap 219, which is located opposite the process chamber 201. A rotating shaft 255 of the rotating mechanism 254 penetrates through the sealing cap 219 and is connected to the boat 217, which will be described later. Rotation of the rotating shaft 255 enables rotation of the boat 217, leading to rotate the wafer 200. The sealing cap 219 may be elevated by means of a boat elevator 115 used as an elevating mechanism that is vertically disposed outside the process tube 203, so that the boat 217 can be transferred into or out of the process chamber 201. A driving control part 237 is electrically connected to the rotating mechanism 254 and the boat elevator 115 (as indicated by A in FIG. 2) to control them to perform desired operations at a desired timing.

The boat 217 used as a substrate holder may be made of a thermally-resistant material such as quartz, silicon carbide or the like, and is constructed to hold a plurality of wafers 200 so that they are horizontally stacked with their centers lined up in uniform arrangement. Furthermore, for the purpose of heat insulation between the heater 206 and the manifold 209, a plurality of adiabatic plates 216 (used as heat-insulating members) of a circular disk shape, which may be made of a heat-insulating material such as quartz, silicon carbide, or the like, are horizontally stacked at the lower portion of the boat 217.

A temperature sensor 263 is disposed, as a temperature detector, inside the process tube 203. A temperature control part 238 is electrically connected to the heater 206 and the temperature sensor 263 (as indicated by D in FIG. 2). The temperature control part 238 controls the heater 206 and the temperature sensor 263 at a desired time to adjust the power supply to the heater 206 based on temperature information detected by the temperature sensor 263, so that the temperature inside the process chamber 201 has a desired temperature distribution.

The gas flow rate control part 235, the pressure control part 236, the driving control part 237 and the temperature control part 238 may also constitute operating parts and input-output parts, and are electrically connected to a main control part 239 that controls the substrate process apparatus as a whole. The gas flow rate control part 235, the pressure control part 236, the driving control part 237, the temperature control part 238 and the main control part 239 make up a controller 240.

The following is a description of a method for forming a thin film on the wafer 200 using CVD (Chemical Vapor Deposition). One embodiment of manufacturing a semiconductor device uses the process furnace 202 with the configuration as described above. In the following discussion, it should be noted that operations of respective parts constituting the substrate process apparatus is controlled by the controller 240.

When a plurality of wafers 200 are loaded into the boat 217 (wafer charging operation), as shown in FIG. 2, the boat 217 holding the plurality of wafers 200 is elevated by the boat elevator 115 and then carried into the process chamber 201 (boat loading operation). In such case, the sealing cap 219 is air-tightly sealed on the lower end of the manifold 209 via the O-ring 220b.

The inside of the process chamber 201 is evacuated by means of the vacuum exhaust equipment 246 so that the pressure therein is maintained at a desired pressure (degree of vacuum). In this case, the pressure inside the process chamber 201 is measured by the pressure sensor 245 and is fed back to the pressure adjusting equipment 242. Based on the measured pressure, the pressure adjusting equipment 242 adjusts the pressure inside the process chamber 201. Further, the inside of the process chamber 201 is heated by the heater 206 so that the temperature therein is maintained at a desired temperature. In such case, the temperature inside the process chamber 201 is measured by the temperature sensor 263 to be fed back to the heater 206. Based on the measured temperature, the power supply to the heater 206 is adjusted so that the temperature inside the process chamber 201 has a desired temperature distribution. Subsequently, the boat 217 is rotated by the rotating mechanism 254, which causes the wafer 200 to rotate.

Thereafter, as shown in FIG. 2, for example, the silicon-containing gas, which is used as a process gas, is supplied from the silicon-containing gas supply source 300a. The supplied silicon-containing gas is provided to the mass flow controller (MFC) 241a, where the flow rate of the silicon-containing gas is controlled to be maintained at a desired level. The so-controlled silicon-containing gas is fed into the process chamber 201 through the gas supply tube 232a. The fed silicon-containing gas flows upward within the process chamber 201 and is discharged from the upper end opening into the tubular space 250, which is in turn exhausted through the exhaust tube 231. When the silicon-containing gas passes through the inside of the process chamber 201, the silicon-containing gas is in contact with the surface of the wafer 200. This causes a thermal CVD reaction that allows for the deposition of a film, for example, a silicon film on the wafer 200.

After a lapse of a predetermined period of time, the inert gas supplied from the inert gas supply source 300d is provided to the mass flow controller (MFC) 241d, which controls the flow rate of the inert gas to be maintained at a desired level. The atmosphere inside the process chamber 201 is displaced into the inert gas and the pressure therein is returned to atmospheric pressure.

Thereafter, the sealing cap 219 is lowered by the boat elevator 115 so that the lower end of the manifold 209 is opened. Then, the processed wafers 200 held by the boat 217 are carried out of the lower end of the manifold 209 to the outside of the process tube 203 (boat unloading operation). The processed wafers 200 are then discharged out of the boat 217 (wafer discharging operation).

The following is a detailed description of a film formation method according to the first embodiment of the present disclosure. The semiconductor manufacturing apparatus 10 as described above may be employed to form a desired film in one of the processes for manufacturing a semiconductor device.

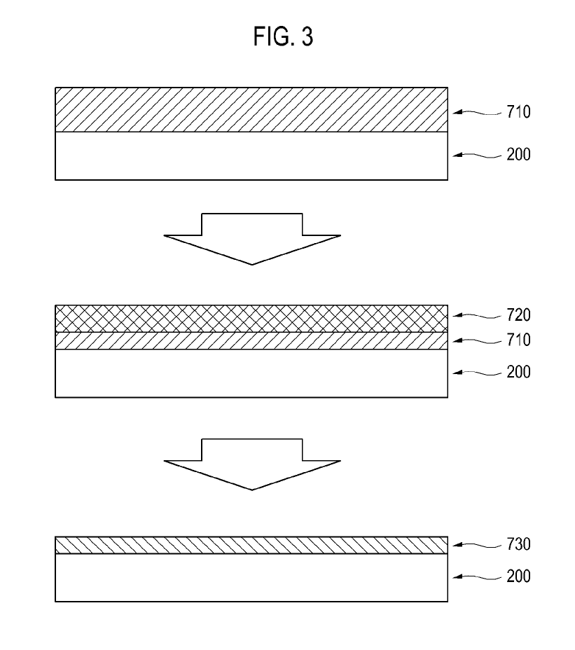

FIG. 3 is a schematic sectional view showing a state of a substrate formed at respective processes according to the first embodiment of the present disclosure. As shown in FIG. 3, in the first embodiment, a film formation process is performed to form a silicon film on the wafer 200 used as a substrate, followed by a modifying process which supplies an oxidation seed to the silicon film, heats the silicon film, and modifies the surface layer of the silicon film into an oxidized silicon film. Finally, a removing process is performed to remove the oxidized silicon film. These processes allow the silicon film to be subjected to heat treatment, thereby modifying the surface layer of the silicon film into oxidized silicon film. As such, it is possible to form the silicon film with a thin thickness and employ the modified oxidized silicon film as a cap film, thereby suppressing the migration of silicon on the surface of the silicon film, which may accompany the heat treatment. This allows formation of a silicon film having a small surface roughness, for example, a poly-silicon film (polycrystalline film). A detailed description for this will be made as follows.

In the following description, the aforementioned processes according to the first embodiment are explained in more detail.

### <Film Formation Process>

The following is a description of a film formation process of forming, for example, an amorphous silicon film 710 on the wafer 200 (used as a substrate) made of silicon or the like. Preferably, at least a silicon-containing gas may be introduced into the process chamber 201 and the amorphous silicon film 710 may be formed on the wafer 200 to have a thickness in the range of 15 nm or higher to 80 nm or lower using a CVD method, for example.

In other embodiments, an oxidized silicon film may be formed on the wafer 200 and then the amorphous silicon film 710 may be formed on the oxidized silicon film by the aforementioned process. This enhances, for example, adhesion between the amorphous silicon film 710 and the oxidized silicon film, which reduces deterioration in performance of the finally-produced semiconductor device and also prevents deterioration in throughput.

Further, examples of the silicon-containing gas may include silane (SiH₄) gas, disilane (Si₂H₆) gas, dichlorosilane (SiH₂Cl₂) gas or the like.

Furthermore, the amorphous silicon film 710 may be formed by introducing the disilane gas onto the wafer 200 to form a seed layer 710a being made of silicon, followed by supplying the silane gas onto the seed layer 710a to form a silicon layer 710b thereon. The formation of the seed layer 710a by supplying the disilane gas onto the wafer 200 allows a crystal nucleus to be uniformly formed on the wafer 200 used as a substrate. The subsequent supply of the silane gas onto the seed layer 710a enables the growth of the crystal nucleus uniformly formed on the wafer 200, thereby uniformly forming the silicon layer 710b. In other words, the silicon film, for example, the amorphous silicon film 710, formed on the wafer 200 includes the seed layer 710a and the silicon layer 710b, thereby improving in-surface uniformity in film thickness.

One example of process conditions under which the wafer 200 is processed inside the process chamber 201, i.e., the seed layer 710a is formed onto the wafer 200 by supplying the disilane gas thereon, may include the following:

Process Temperature: the range of 390° C. or higher to 480° C. or lower

Process Pressure: the range of 40 Pa or higher to 120 Pa or lower

Disilane Gas Supply Flow Rate: the range of 50 sccm or higher to 500 sccm or lower

By maintaining the respective process conditions above at a constant level in the respective ranges, the silicon layer 710b made of silicon is formed on the wafer 200.

Further, one example of process conditions under which the wafer 200 is processed inside the process chamber 201, i.e., the silicon layer 710b is formed on the seed layer 710a, may include the following:

Process Temperature: the range of 490° C. or higher to 540° C. or lower

Process Pressure: the range of 40 Pa or higher to 200 Pa or lower

Silane Gas Supply Flow Rate: the range of 500 sccm or higher to 2,000 sccm or lower

By maintaining the respective process conditions above at a constant level in the respective ranges, the silicon layer 710b is formed on the seed layer 710a.

The film formation process as described above allows the amorphous silicon film 710 having a small surface roughness to be formed on the wafer 200.

Further, the seed layer 710a made of silicon may be formed to have a film thickness of 1 nm or higher. It has been appreciated that when the thickness of the amorphous silicon film 710 is 15 nm, inclusive of the thickness of the seed layer 710a (which is formed by supplying the disilane gas) being 1 nm and that of the silicon layer 710b (which is formed by supplying the silane gas) being 13 nm, it is possible to assure a high degree of step coverage, for example, step coverage of 95%. This allows the application of the present embodiment to a next-generation memory such as 3-dimensional memory (3D memory).

Further, while in the above description, the film formation conditions have been explained to form the amorphous silicon film 710 using both the disilane and the silane gas, the present disclosure is not limited thereto. For example, in other embodiments, the amorphous silicon film 710 may be formed using any one of silicon-containing gases, any one of the other silicon-containing gases, or any combination thereof.

Further, while in the above description, the film formation process has been explained to be performed by means of a CVD method, the present disclosure is not limited thereto. For example, in other embodiments, an ALD (Atomic Layer Deposition) method may be employed.

### <Modifying Process>

Subsequently, the modifying process is performed by supplying an oxidation seed to the silicon film, for example, the amorphous silicon film 710, heating the silicon film subjected to oxidation, and modifying the surface layer of the silicon film into an oxidized silicon film.

Oxygen (O₂) is supplied into the process chamber 201 as for example, at least the oxidation seed, and then a silicon film, for example, the amorphous silicon film 710 is subjected to heat treatment, modifying the surface layer of the silicon film into an oxidized silicon film. The amorphous silicon film 710 formed by the modifying process may be preferably formed to have a film thickness in the range of 2 to 50 nm.

As such, the surface layer of the amorphous silicon film 710 is modified by the oxidation seed supplied thereto into an oxidized silicon film 720, while a silicon film, for example, the amorphous silicon film 710 is changed into poly-silicon film 730 by heat treatment. Further, in this case, the poly-silicon film 730 may be formed having a thinner thickness than that of the amorphous silicon film 710.

In addition, the oxidized silicon film 720 formed by the modifying process may serve as a cap film, by which the migration of silicon residing on an interface between silicon films formed on the wafer, particularly, the poly-silicon film 730 and the oxidized silicon film 720, is suppressed during the modification of the amorphous silicon film 710 into the poly-silicon film 730 by heat treatment. Specifically, a surface roughness (in RMS) of the poly-silicon film 730 that is exposed by the subsequent removing process described below in detail can be small because the migration of silicon residing on the surface layer of the poly-silicon film 730 is suppressed.

One example of process conditions under which the wafer 200 is processed inside the process chamber 201 may include the following:

Process Temperature: the range of 700° C. or higher to 950° C. or lower

Process Pressure: the range of 100 Pa or higher to 100,000 Pa or lower

Oxygen Gas Supply Flow Rate: the range of 4 sccm or higher to 10 sccm or lower

By maintaining the process conditions above at a constant level in the respective ranges, the surface layer of the amorphous silicon film 710 is modified by the oxidation seed supplied thereto into an oxidized silicon film 720, while a silicon film, for example, the amorphous silicon film 710 is changed into poly-silicon film 730 by heat treatment.

While the oxidation seed is supplied onto the amorphous silicon film 710 which is then subjected to heat treatment, thereby being changed into the poly-silicon film 730, the surface layer of the amorphous silicon film 710 is modified by the oxidation seed supplied thereto into an oxidized silicon film 720.

In such case, the oxidized silicon film 720 modified by the oxidation seed may serve as a cap film, which suppresses the migration of silicon residing on an interface between silicon films heat-treated to form the poly-silicon film 730, particularly, the poly-silicon film 730 and the oxidized silicon film 720. In addition, since the surface layer of the amorphous silicon film 710 is modified into the oxidized silicon film 720, the poly-silicon film 730 may be formed to have a thin thickness. In other words, the process conditions such as the amount of oxidation seed, for example, an oxygen gas, to be supplied at the modifying process, a pressure (process pressure) or temperature (process temperature) in the process chamber 201, or the like, may be controlled. This allows for controlling the amount of modification into the oxidized silicon film 720, i.e., a film thickness of the oxidized silicon film 720 to be modified, thereby controlling a film thickness of the poly-silicon film 730.

Further, although in the above embodiment, the oxidation gas has been explained as the oxidation seed, preferably, the oxidation gas and hydrogen gas may be supplied into the process chamber 201 independently of each other in the modifying process. This causes the initial oxidation reaction to be performed at a high speed, which may significantly reduce the difference in oxidation speed depending on plane directions in silicon, even when more than one plane direction is presented on the wafer 200 made of silicon, thereby uniformly performing the modifying process. However, the present embodiment is not limited thereto but may use other methods employing an oxygen-containing gas such as H₂O gas.

### <Removing Process>

Next, the removing process for removing the oxidized silicon film 720 formed during the modifying process is performed. By the removing process, the oxidized silicon film 720 is removed to expose the poly-silicon film 730.

For example, at least nitrogen trifluoride (NF₃) gas is supplied into the process chamber 201 to remove the oxidized silicon film 720 using dry etching. In such case, the oxidized silicon film 720 reacts with the nitrogen trifluoride gas, so that silicon residing on the oxidized silicon film 720 is combined with nitrogen contained in the nitrogen trifluoride gas to form a silicon-fluoride-containing compound (SiₓF_{y}, x and y being an integer), while oxygen residing on the oxidized silicon film 720 is combined with nitrogen contained in the nitrogen trifluoride gas to form a nitrogen-oxide-containing compound (NO_{z}, z being an integer). The gas including the above compounds is evacuated from the process chamber 201 to remove the oxidized silicon film 720.

As a result, it is possible to obtain the poly-silicon film 730 having a small surface roughness, which is formed on the wafer 200 by the modifying process as described above.

In the present embodiment, the nitrogen trifluoride (NF₃) gas is employed, but not limited thereto. In other embodiments, a halogen-containing gas containing fluorine or chlorine such as chlorine trifluoride (ClF₃) gas, fluorine (F₂) gas or the like may be used. Furthermore, the removal of the oxidized silicon film 720 may be performed by discharging the wafer 200 from the semiconductor manufacturing apparatus 10 and followed by using a chemical-based wet etching through the use of other equipment, instead of using the dry etching as described above. Preferably, a rare hydrofluoric acid solution, which is diluted in a concentration of for example, 1%, may be used in the wet etching to remove the oxidized silicon film 720, thereby forming the poly-silicon film 730 having a small surface roughness. It is described in this embodiment that the rare hydrofluoric acid solution is used as the chemical, but it is not limited thereto. In other embodiments other halogen-containing solutions may be used. Also, a solution diluted in a higher concentration may be used.

After completion of the series of processes described above, the supply of the process gas into the process chamber is suspended, followed by supplying the inert gas from the inert gas supply source to the process chamber 201, so that the atmosphere inside the process chamber 201 is displaced into the inert gas and a pressure therein is returned to atmospheric pressure.

Thereafter, the sealing cap 219 is lowered by the elevating motor 122 so that the lower end of the manifold 209 is opened. The processed wafers 200 held by the boat 217 are then discharged from the lower end of the manifold 209 outside of the process chamber 201 (boat unloading operation). The boat 217 is in standby state at a predetermined location until all of the processed wafers 200 held by the boat 217 are cooled. Subsequently, if the wafers 200 in the boat 217 being in standby state are cooled to a predetermined temperature, the wafers 200 in the boat 217 are picked up by the substrate transfer part 28 and then carried to an empty pod 16 positioned in the pod opener 24 for accommodation therein. Thereafter, the pod carrier 20 carries the pod 16 containing the wafers 200 into the pod shelf 22 or the pod stage 18. Thus, a series of operations in the semiconductor manufacturing apparatus 10 is completed.

### <Comparison>

In the following, the poly-silicon film 730 formed by the aforementioned method is compared with a sample film, i.e., a poly-silicon film 750 formed on a wafer 200.

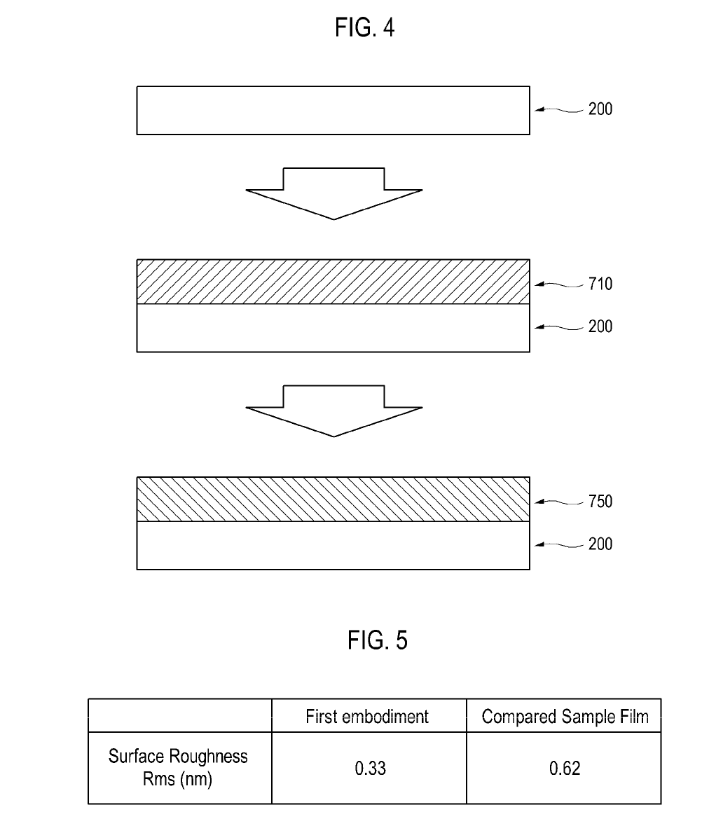

A description will made as to a method of forming a sample film. FIG. 4 is a schematic cross-sectional view of films which are formed by respective sample formation processes. The sample film is formed by firstly forming an amorphous silicon film 710 on a wafer 200, followed by thermally-treating the amorphous silicon film 710 and modifying the amorphous silicon film 710 into a poly-silicon film 750.

Further, the method of forming the amorphous silicon film 710 used in the formation of the sample film is identical to that used in the first embodiment described above. The process conditions in the heat treatment are given as follows.

When a sample film 750 is formed inside the process chamber 201, one example of the process conditions under which the amorphous silicon film 710 is subjected to heat treatment may include the following:

Process Temperature: the range of 650° C. or higher to 950° C. or lower

Process Pressure: the range of 5,000 Pa or higher to 1,000,000 Pa or lower

Nitrogen Gas Supply Flow Rate: the range of 500 sccm or higher to 2,000 sccm or lower

By maintaining the process conditions above at a constant level in the respective ranges, the amorphous silicon film 710 is subjected to heat treatment.

In some embodiments, a temperature and a time period required for the heat treatment may be properly adjusted depending on conditions adapted for a substrate to be heat-treated.

FIG. 5 shows the result of the comparison between a surface roughness of the film, which is formed according to the first embodiment, and that of the poly-silicon film 750 (sample film). In both cases, a poly-silicon film (polycrystalline silicon film) with a thickness of 15 to 80 nm has been formed on the wafer 200. However, the surface roughnesses (in RMS) are significantly different in both films. The comparison shows that while the surface roughness (in RMS) of the poly-silicon film 750 used as a sample film has a high magnitude of 0.62 nm, the poly-silicon film 730 formed according to the first embodiment has a surface roughness of a reasonable magnitude of 0.33 nm. The reason for this difference is that silicon residing on the surface of the amorphous silicon moves during the heat treatment of the sample film. On the other hand, in the first embodiment, the amorphous silicon film 710 is subjected to heat treatment to be displaced into the poly-silicon film 730 while the surface layer of the amorphous silicon film 710 is modified into the oxidized silicon film 720 by the oxidation seed supplied thereto. This allows the so-formed oxidized silicon film 720 to serve as a cap film, preventing the migration of silicon residing on the interface between silicon films constructing the poly-silicon film, particularly, the poly-silicon film 730 and the oxidized silicon film 720, the migration being caused by heat treatment. In addition, the poly-silicon film 730, which is exposed at the removing process, may be formed to have a small surface roughness.

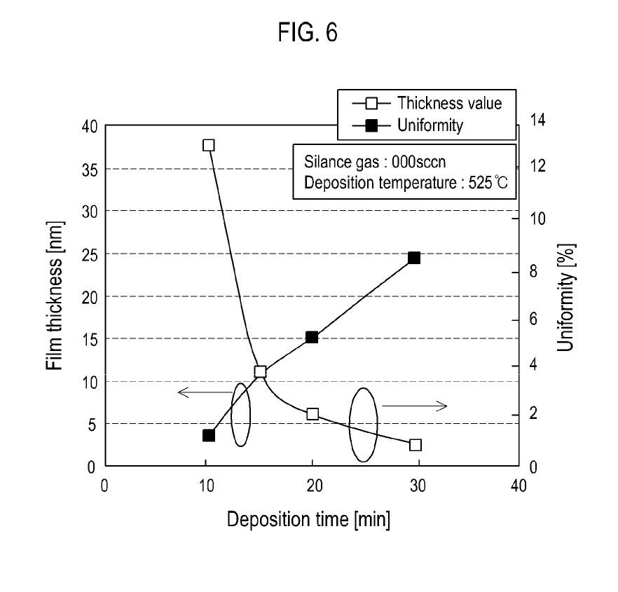

FIG. 6 shows the relationship between measured film thickness values in the amorphous silicon film and in-surface uniformities measured at respective film thickness values. In FIG. 6, the horizontal axis depicts a film formation time period (min), while the left vertical axis depicts a film thickness value of the formed amorphous silicon film and the right vertical axis depicts an in-surface uniformity (%) at respective film thickness values in the amorphous silicon film formed on the wafer 200. As shown in FIG. 6, the in-surface uniformity of the amorphous silicon film drastically deteriorates as the film thickness decreases. Therefore, it is contemplated that a flat surface may not be obtained by employing only the amorphous silicon film formation process as the scale of a semiconductor device decreases, thereby making the application of the process to the semiconductor device difficult.

According to the first embodiment of the present disclosure, the poly-silicon film 730 with a small surface roughness can be formed, which is advantageous in application to a decreased scale of semiconductor device requiring a silicon film with a small film thickness. During the process of manufacturing the semiconductor device, for example, it is possible to uniformly form a silicon film, and also enhance adhesiveness between the poly-silicon film 730 and a film to be formed thereon. Furthermore, according to the present disclosure, it is possible to manufacture a semiconductor device with a better performance in a stable manner.

The embodiments may have at least one of the following effects: (1) a poly-silicon film with a small surface roughness can be formed; (2) by controlling an oxidation seed supply condition, the film thickness of a poly-silicon film to be formed can be controlled; (3) in connection with item (1), in the film formation process, it is possible to form a poly-silicon film with a small surface roughness and a better in-surface uniformity by the use of a seed layer being made of silicon formed by disilane gas and a silicon layer formed by silane gas; (4) in connection with item (1), in the semiconductor device manufacturing process, it is possible to uniformly form an insulating film made of silicon; (5) in connection with item (1), it is possible to obtain a better step coverage if the embodiments are applied to, for example, a structure such as a trench with a high aspect ratio; (6) in connection with item (1), it is possible to enhance adhesiveness between a poly-silicon film and a film to be formed thereon; and (7) it is possible to manufacture a semiconductor device with better performance in a stable manner, thereby obtaining an increase in throughput.

Moreover, in the aforementioned embodiments, a series of film formation processes is performed by one semiconductor manufacturing apparatus 10, but not limited thereto, it may be performed using processing equipment dedicated to respective process.

Likewise, the present disclosure is not limited to batch-type equipment and is also applicable to single wafer type equipment.

Furthermore, while the present disclosure has been explained as to the formation of the poly-silicon film, it is also applicable to other epitaxial and CVD films, for example, a silicon nitride film or the like.

Hereinafter, the preferred aspects of the present disclosure will be additionally stated.

A first aspect of the present disclosure may provide a semiconductor device manufacturing method, including: forming a silicon film on a substrate; supplying an oxidation seed onto the substrate, performing heat treatment on the silicon film; modifying the surface layer of the silicon film into an oxidized silicon film; and removing the oxidized silicon film.

A second aspect of the present disclosure provides a substrate process apparatus that includes: a process chamber where a substrate is processed; a silicon-containing gas supply system configured to supply at least a silicon-containing gas into the process chamber; an oxygen-containing gas supply system configured to supply at least an oxygen-containing gas into the process chamber; a halogen-containing gas supply system configured to supply at least a halogen-containing gas into the process chamber; and a controller configured to control the silicon-containing gas supply system to supply at least the silicon-containing gas into the process chamber to thereby form the silicon film on the substrate, control the oxygen-containing gas supply system to supply the oxygen-containing gas into the process chamber to perform heat treatment on the silicon film and modify the surface layer of the silicon film into an oxidized silicon film, and control the halogen-containing gas supply system to supply the halogen-containing gas into the process chamber to remove the oxidized silicon film.

A third aspect of the present disclosure provides a substrate process method that includes: forming a silicon film on a substrate; supplying an oxidation seed onto the substrate; performing heat treatment on the silicon film; modifying the surface layer of the silicon film into an oxidized silicon film; and removing the oxidized silicon film.

The process of forming a film according to the first aspect may include supplying disilane gas into the process chamber to form a seed layer made of silicon on the substrate, followed by supplying silane gas into the process chamber to form the silicon film on the seed layer.

The process of forming a film according to the first aspect may include supplying disilane gas into the process chamber to form the seed layer made of silicon on the substrate, followed by stopping the supply of the disilane gas into the process chamber, and followed by supplying silane gas into the process chamber to form the silicon film on the seed layer.

In the process of forming a film according to the above aspects, a film thickness of the seed layer may be in the range of 1 nm or higher.

The process of removing according to the above aspects may include supplying the halogen-containing gas onto the substrate to remove the oxidized silicon film.

According to the present disclosure in some embodiments, it is possible to improve the quality of substrate and the performance of semiconductor device by reducing the amount of deterioration of the substrate during treatment.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device manufacturing method, comprising:
forming a silicon film on a substrate;
modifying the surface layer of the silicon film into an oxidized silicon film by supplying an oxidation seed onto the substrate, and performing heat treatment on the silicon film; and
removing the oxidized silicon film.

2. The method of claim 1, wherein the modifying of the surface layer of the silicon film into the oxidized silicon film comprises modifying other areas of the silicon film which are not oxidized silicon film.

3. The method of claim 2, wherein the silicon film formed in the forming of the silicon film on the substrate is an amorphous silicon film, and other areas of the silicon film that are not oxidized silicon film after modifying the surface layer of the silicon film are modified into a poly-silicon film from the amorphous silicon film.

4. The method of claim 1, wherein the modifying and the removing are performed within a same process chamber.

5. The method of claim 4, wherein, the removing further comprises removing the oxidized silicon film by supplying a halogen-containing gas into the process chamber.

6. The method of claim 1, wherein the modifying and the removing are performed in different chambers.

7. The method of claim 6, wherein the removing further comprises removing the oxidized silicon film by a chemical-based wet etching.

8. The method of claim 1, wherein the forming further comprises supplying disilane gas into the process chamber to form a seed layer made of silicon on the substrate, and supplying silane gas into the process chamber to form the silicon film on the seed layer.

9. The method of claim 8, wherein the disilane gas is supplied in the formation of the seed layer, and the silane gas is supplied in the formation of the silicon film on the seed layer.

10. The method of claim 1, wherein the modifying comprises supplying the oxidation seed onto the silicon film when process pressure falls within the range of 100 Pa or higher to 100,000 Pa or lower.

11. A substrate processing apparatus, comprising:
a process chamber where a substrate is processed;
a silicon-containing gas supply system configured to supply at least a silicon-containing gas into the process chamber;
an oxygen-containing gas supply system configured to supply at least an oxygen-containing gas into the process chamber;
a halogen-containing gas supply system configured to supply at least a halogen-containing gas into the process chamber; and
a controller configured to control the silicon-containing gas supply system to supply at least the silicon-containing gas into the process chamber to thereby form the silicon film on the substrate, control the oxygen-containing gas supply system to supply the oxygen-containing gas into the process chamber to perform heat treatment on the silicon film, and to modify the surface layer of the silicon film into an oxidized silicon film, and control the halogen-containing gas supply system to supply the halogen-containing gas into the process chamber to remove the oxidized silicon film.

12. A substrate process method, comprising:
forming a silicon film on a substrate;
modifying the surface layer of the silicon film into an oxidized silicon film by supplying an oxidation seed onto the substrate, and performing heat treatment on the silicon film; and
removing the oxidized silicon film.
